(19) United States
(12) Patent Application Publication
(10) Pub. No.: US 2022/0396077 A1
(43) Pub. Date: Dec. 15, 2022

(54) ELECTRICAL CONNECTORS

(71) Applicant: Hewlett-Packard Development Company, L.P., Fort Collins, CO (US)

(72) Inventors: Paul David Schweitzer, Corvallis, OR (US); Max Richard Quinn, Corvallis, OR (US); Daren L. Forrest, Corvallis, OR (US); Thomas Stafford Johnson, Corvallis, OR (US)

(73) Assignee: Hewlett-Packard Development Company, L.P., Fort Collins, CO (US)

(21) Appl. No.: 16/958,089

(22) PCT Filed: Oct. 25, 2019
(86) PCT No.: PCT/US2019/058050

§ 371 Date: Jun. 25, 2020

(51) Int. Cl. B41J 2/175; H05K 3/24

(52) U.S. Cl. CPC B41J 2/1753; H05K 3/241; H05K 3/06

(57) ABSTRACT

Examples of electrical connectors are provided herein. In some examples, an electrical connector includes a contact pad at a first end of a route. In some examples, the electrical connector includes a bond at a second end of the route. In some examples, the contact pad and the bond include a copper layer on a substrate, a nickel layer on the copper layer, and a gold layer on the nickel layer. In some examples, the gold layer has a first thickness on the contact pad and has a second thickness on the bond. In some examples, the second thickness is greater than the first thickness.

### BACKGROUND

Electronic technology has advanced to become virtually ubiquitous in society and has been used to improve many activities in society. For example, electronic devices are used to perform a variety of tasks, including work activities, communication, research, and entertainment. Electronic technology is implemented from electronic circuits. Different varieties of electronic circuits may be implemented to provide different varieties of electronic technology.

### BRIEF DESCRIPTION OF THE DRAWINGS

FIG. 1 is a diagram illustrating an example of a print component;

FIG. 2 is a diagram illustrating an example of an electrical connector;

FIG. 3A is a diagram illustrating an example of a body of a print component;

FIG. 3B is a diagram illustrating an example of a lid of a print component;

FIG. 4 is a perspective view diagram of an example of an electrical connector; and

FIG. 5 is a flow diagram illustrating one example of a method for manufacturing a conductive metal route.

### DETAILED DESCRIPTION

An electrical connector is a metal connector that is capable of carrying an electrical signal or charge. In some examples, electrical connectors may be utilized to couple or connect electronic components. For instance, an electrical connector may be utilized to couple or connect electronic circuitries. Electrical connectors may be designed to handle certain scenarios in some examples. For instance, some electrical connectors may be designed to withstand frictional forces and/or to enable wire bonding.

In some examples, electrical connectors may be included in a replaceable print component such as a print liquid supply unit or print head. Print liquid is a fluid for printing. Examples of print liquid include ink and fusing agent. In some examples, print liquid may be supplied to a printer. For instance, the print liquid may be provided from the print component to a print head assembly. A print head assembly is a device that includes a print head to extrude the print liquid. In some examples, some replaceable print components may include a print liquid level sensor (e.g., digital ink level sensor) to indicate a print liquid level with improved accuracy. The print liquid level sensor may be an integrated circuit to be assembled and installed in the replaceable print component. In some examples, a flexible circuit die assembly may be utilized to satisfy functionality and integration issues. For example, one issue is to provide an electrical connection interface to a printer using a flexible circuit (e.g., polyimide-based flexible circuit). The electrical connection may be designed to survive high frictional forces from a sliding connector on the printer, while providing electrical traces that enable gold-ball wire bonding. While examples of electrical connectors in replaceable print components are given herein, examples of the techniques described herein may be implemented in other electronic devices.

In some examples, a print component may be constructed of thermoplastics. Thermoplastics may be injection molded and may be compatible with high volume manufacturing and/or assembly methods. It may be beneficial for the construction materials (e.g., materials to construct components of the print component) to be compatible with the print liquid and/or to be robust to environmental conditions during shipping/handling. In some examples, print components may be constructed from thermoplastics such as polypropylene (PP), low-density polyethylene (LDPE), high-density polyethylene (HDPE), polyethylene terephthalate (PET), polycarbonate (PC), and/or blends thereof.

Throughout the drawings, similar reference numbers may designate similar, but not necessarily identical, elements. Similar numbers may indicate similar elements. When an element is referred to without a reference number, this may refer to the element generally, without necessary limitation to any particular Figure. The figures are not necessarily to scale, and the size of some parts may be exaggerated to more clearly illustrate the example shown. Moreover, the drawings provide examples and/or implementations in accordance with the description; however, the description is not limited to the examples and/or implementations provided in the drawings.

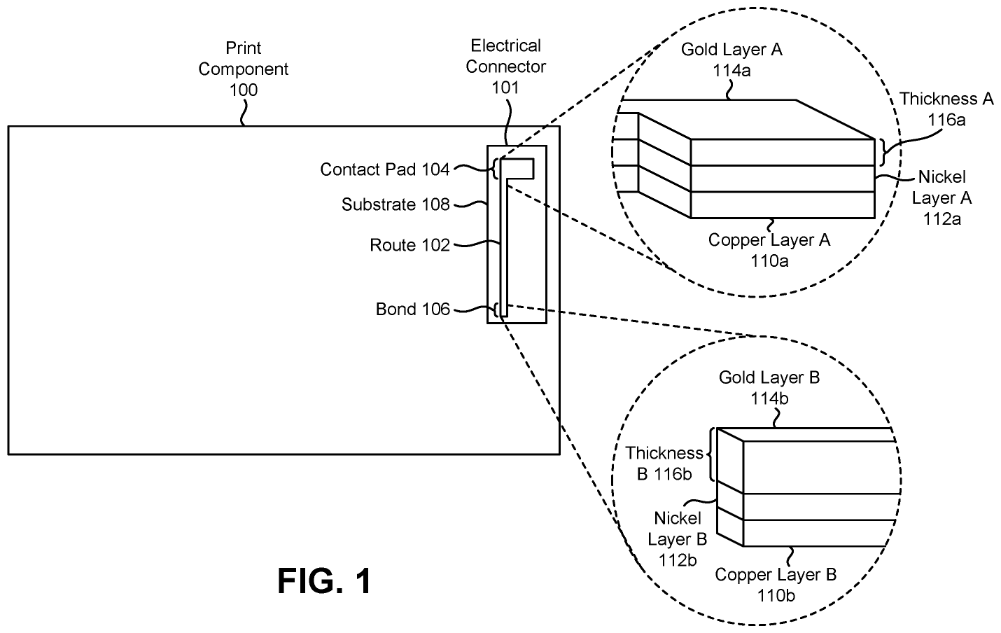

FIG. 1 is a diagram illustrating an example of a print component 100. A print component 100 is a device that is connectable to a host print system (e.g., ink jet printer, three-dimensional (3D) printer, laser printer, etc.). For example, the print component 100 may be a replaceable print component to connect to a host print system. Examples of the print component 100 include print liquid supply units, print cartridges, print heads, toner cartridges, etc.

In some examples, the print component 100 includes an electrical connector 101. The electrical connector 101 may include a contact pad 104 at a first end of a route 102. A route is a metal trace, line, or wire. A contact pad is a metal surface for contacting a connector. For example, the contact pad 104 may be positioned on the print component 100 to contact a connector of a host print system when the print component is installed or attached to the host print system.

In some examples, the electrical connector 101 includes a bond 106 at a second end of the route 102. A bond is a metal area for bonding. Examples of the bond 106 may include metal plates, balls, pads, etc., that may be utilized to connect to (e.g., bond to, fuse to, join with, etc.) a wire or other connector. For example, the bond 106 may be a wire bond pad.

In the example illustrated in FIG. 1, magnified perspective side views of the contact pad 104 and the bond 106 are provided. The contact pad 104 may include copper layer A 110a on a substrate 108, nickel layer A 112a on copper layer A 110a, and gold layer A 114a on nickel layer A 112a. The bond 106 may include copper layer B 110b on the substrate 108, nickel layer B 112b on copper layer B 110b, and gold layer B 114b on nickel layer B 112b. Copper layer A 110a and copper layer B 110b may be separate copper layers or may be parts of one copper layer. Nickel layer A 112a and nickel layer B 112b may be separate nickel layers or may be parts of one nickel layer. Gold layer A 114a and gold layer B 114b may be separate gold layers or may be parts of one gold layer. In some examples, a copper layer (e.g., copper layer 110a-b), a nickel layer (e.g., nickel layer 112a-b), and/or a gold layer (e.g., gold layer 114a-b) may span a route (e.g., may extend along the entire route 102).

Gold layer A 114a may have thickness A 116a on the contact pad 104, and gold layer B 114b may have thickness B 116b on the bond 106. Thickness B 116b may be greater than thickness A 116a in some examples. In some examples, thickness B 116b may be greater than thickness A 116a by 20 nanometers (nm) or more (e.g., 20 nm, 30 nm, 35 nm, 40 nm, 50 nm, etc.). The increased thickness of gold layer B 114b may beneficially provide more metal for wire bonding with gold wire (e.g., gold ball bonding). In some examples, thickness B 116b of the bond 106 may be thicker than a diameter of a gold wire to be attached to the bond 106. In some examples, gold layer A 114a and/or gold layer B 114b may be unalloyed gold (Au). For instance, gold layer A 114a and/or gold layer B 114b may be gold (e.g., “soft” gold) with a purity greater than 99% (e.g., greater than or equal to 99.9% purity) and/or with a Knoop hardness that is less than or equal to 90. Unalloyed gold may provide improved adhesion with gold wire in gold ball bonding. In some examples, a palladium layer or layers may be utilized instead of a gold layer or layers for the contact pad 104 and/or the bond 106.

In some examples, gold layer A 114a with thickness A 116a and gold layer B 114b with thickness B 116b may be formed in one gold bath. For example, gold layer A 114a and gold layer B 114b with differing thicknesses 116a-b may be formed with an electroplating technique in a gold bath, where the gold bath includes a solution of gold. Gold in the gold solution may form a layer of gold on the contact pad 104 and the bond 106 when an electrical current is applied to the electrical connector 101 (e.g., route 102). Electroplating a metal (e.g., gold, palladium, etc.) in a single bath may be beneficial by reducing manufacturing costs of multiple baths and/or multiple baths with different kinds of gold.

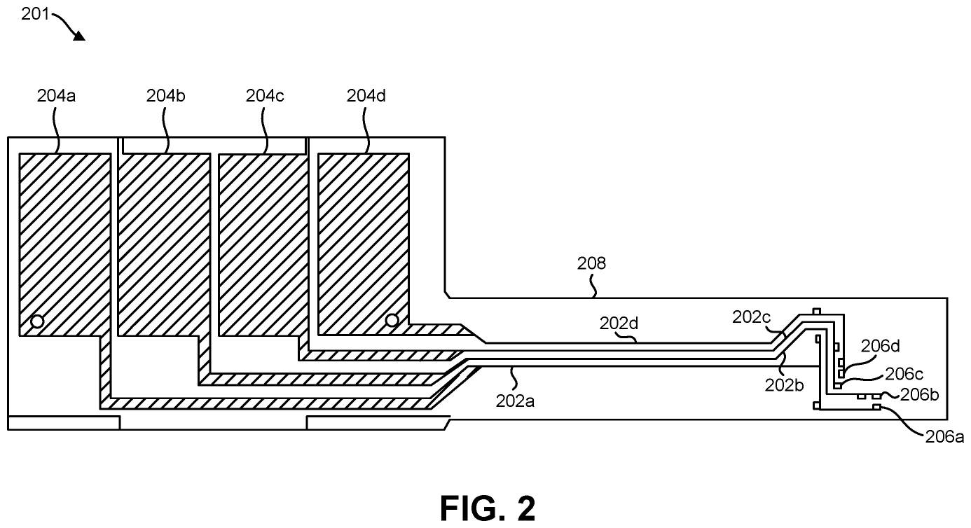

FIG. 2 is a diagram illustrating an example of an electrical connector 201. In some examples, the electrical connector 201 described in relation to FIG. 2 may be an example of the electrical connector 101 described in relation to FIG. 1. In some examples, the electrical connector 201 may be included in a print component or print liquid container.

The electrical connector 201 may include a substrate 208, contact pads 204a-d, routes 202a-d, and bonds 206a-d (e.g., wire bond pads). Additional wire bond pads are illustrated in FIG. 2, which may be at an end of a route or between ends of a route. In some examples, a contact pad and a bond may be on a single side of a substrate. For example, the contact pads 204a-d and the bonds 206a-d (e.g., wire bond pads) may be on one side of the substrate 208 (e.g., without via(s), route(s), etc., penetrating the substrate 208 and/or without trace(s), route(s), wire(s), etc., on another side of the substrate 208). In some examples, each of the routes 202a-d may be a metal route including a copper layer, a nickel layer on the copper layer, and a gold layer on the nickel layer.

A contact surface area of a contact pad is an area of a side (e.g., side for contact) of the contact pad. For instance, a contact pad may have an enlarged shape (e.g., rectangular shape, circular shape, irregular shape, etc.) relative to a route connected to the contact pad. The contact surface area may include an area (e.g., total area) of the surface of the enlarged shape of the contact pad. For instance, a contact surface area of a rectangular contact pad may be calculated with two dimensions of the surface of the rectangular contact pad. A surface area of a bond is an area of a side (e.g., side for bonding) of the bond. For instance, a bond may have an enlarged shape (e.g., rectangular shape, circular shape, irregular shape, etc.) relative to a route connected to the bond. The surface area of a bond may include an area (e.g., total area) of the surface of the enlarged shape of the bond. In some examples, a contact pad may have a first contact surface area that is greater than a second surface area of a bond. For example, each of the contact pads 204a-d has a greater surface area than each corresponding bond 206a-d (e.g., wire bond pad). In some examples, the first contact surface area may be greater than the second surface area by a ratio of at least 10 (e.g., 10, 50, 100, 150, 200, 250, 300, 350, 400, etc.). In some examples, a contact pad may have a surface area of approximately 4.27 millimeters (mm)×2.13 mm.

In some examples, a contact pad may have a lesser thickness than a bond. For example, each of the contact pads 204a-d has a lesser thickness than each corresponding bond 206a-d (e.g., wire bond pad). In some examples, the thickness of the gold layer on the contact pads 204a-d may be less than 0.1 micrometers (μm). Less gold on the contact pads 204a-d may be beneficial by reducing frictional forces and wear. In some examples, the thickness of the gold layer on the bonds 206a-d (e.g., wire bond pads) may be greater than 0.15 μm. More gold on the bonds 206a-d may be beneficial by improving wire bond adhesion.

In some examples, plating a harder nickel (Ni) layer on top of the copper (Cu) layer, followed by a layer of gold (Au) for the contact pads 204a-d may be beneficial. For example, the nickel layer may provide a harder surface for a spring connector (of a host print system, for example) to ride against, while protecting the softer copper underneath from wear, exposure, and/or corrosion. A layer of gold on the contact pads 204a-d may provide a lubricant to reduce frictional forces with the spring connector. A thicker layer of gold on the bonds 206a-d may provide more metal for intermetallic bonding. The thicker layer of gold, relative to contact pads 204a-d may be formed through the use of electrolytic current density differences due to different sizes of the contact pads 204a-d relative to the bonds 206a-d . For example, each of the contact pads 204a-d may have a lower current density than each corresponding bond 206a-d (e.g., wire bond pad) during manufacturing to produce the lesser thickness on the contact pads 204a-d relative to the bonds 206. For instance, bonds 206a-d may have a smaller area relative to the contact pads 204a-d, which may increase current density in the bonds 206a-d relative to the larger contact pads 204a-d. The increased current density in the bonds 206a-d may cause the bonds 206a-d to plate more quickly (e.g., at a faster plating rate) than the contact pads 204a-d (e.g., at a slower plating rate), which may create a thicker gold layer on the bonds 206a-d relative to the contact pads 204a-d.

In some examples, a first route 202a may be a serial data line, a second route 202b may be a clock line, a third route 202c may be a power line, and/or a fourth route 202d may be a ground line. In some examples, the serial data line, clock line, power line, and/or ground line may be arranged in a different order and/or may correspond to different routes (e.g., contact pads and/or bonds). In some examples, a serial data line is a line that carries serial data to and/or from sensor circuitry coupled to the electrical connector 201. In some examples, a clock line is a line that carries a clock signal to and/or from sensor circuitry coupled to the electrical connector 201. In some examples, a power line is a line that carries power (e.g., a voltage and/or electrical current) to and/or from sensor circuitry coupled to the electrical connector 201. In some examples, a ground line is a line that provides grounding for sensor circuitry coupled to the electrical connector 201. In some examples, the sensor circuitry may be coupled to the bonds 206a-d with gold wires. In some examples, the sensor circuitry may detect a print liquid level (e.g., a level of print liquid in a print liquid supply unit, a print liquid container, a print cartridge, etc.). In some examples, the sensor circuitry may sense strain and/or pressure. It may be beneficial to provide an electrical connector 201 that enables electrical signaling and/or power to pass from the exterior of a print component to the interior of the print component.

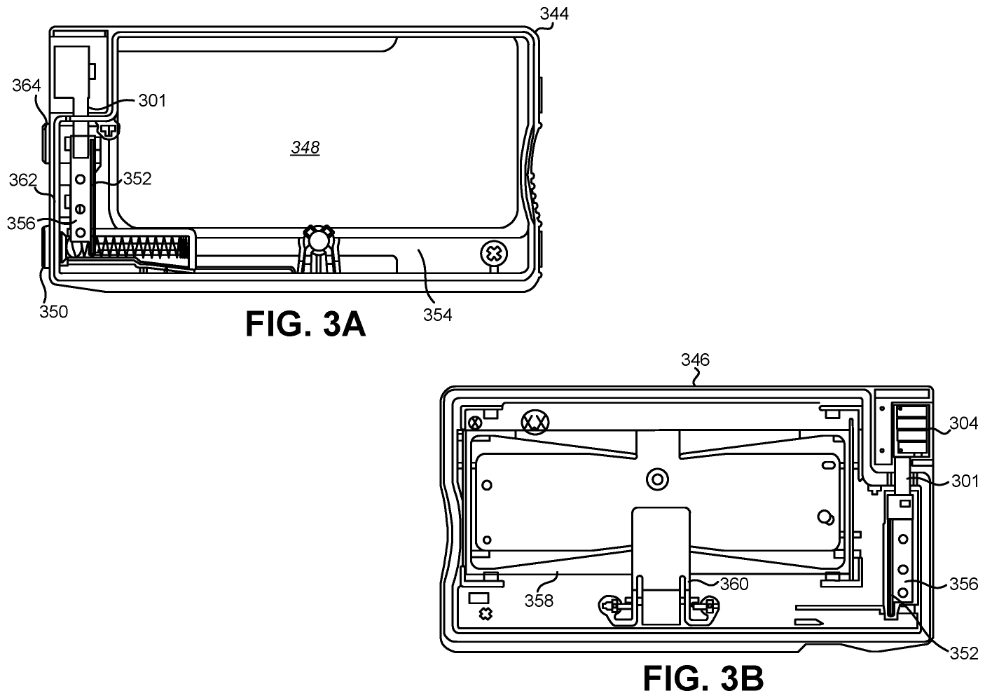

FIG. 3A is a diagram illustrating an example of a body 344 of a print component. The body 344 may be an example of a part of the print component 100 described in connection with FIG. 1.

FIG. 3B is a diagram illustrating an example of a lid 346 of a print component. The lid 346 may be an example of a part of the print component 100 described in connection with FIG. 1. FIG. 3A and FIG. 3B are described together.

Examples of the print component include print liquid containers, cartridges, supplies, print liquid supply cartridges, etc. The print component may contain and/or transfer print liquid (e.g., ink, agent, etc.). In some examples, the print component may be designed to interface with a host device. A host device is a device that uses and/or applies print liquid. Examples of a host device include printers, ink jet printers, 3D printers, etc. For example, it may be beneficial to replenish or replace the print component when some or all of the print liquid has been utilized.

In some examples, the print component may include a regulator assembly. A regulator assembly is a device to regulate pressure within the print component. For example, the regulator assembly may include a pressure chamber 348. The pressure chamber 348 is a structure that is at least partially expandable and/or collapsible. For example, the pressure chamber 348 may hold a gas (e.g., air) or fluid. In some examples, the pressure chamber 348 may expand when inflated and/or may collapse when deflated. Examples of the pressure chamber 348 and/or regulator assembly may include a bag or balloon. In some examples, the regulator assembly may include a spring and/or a lever. The spring and/or lever may be utilized with the pressure chamber 348 (e.g., bag or balloon) to regulate the pressure in the print component. Another example of the pressure chamber 348 and/or regulator assembly is a film on a structure (e.g., rib structure(s)) of the print component.

In some examples, the print component may include a port 350. The port 350 is an opening in the print component. An example of the port 350 is a print liquid outlet. For example, the print component may supply print liquid to a printer (e.g., print head) via the port 350.

In some examples, the print component may include sensor circuitry 352. The sensor circuitry 352 is electronic circuitry to detect a condition or conditions. In some examples, the sensor circuitry 352 may include a liquid level sensor and/or a strain or pressure sensor. In some examples, the sensor circuitry 352 may be mounted on and/or in a sensor support 356. The sensor support 356 is a structure that supports (e.g., carries) the sensor circuitry 352. In some examples, the sensor support 356 may be a substrate or board. In some examples, the sensor support 356 may be molded from a glass-filled engineering plastic for stability and to withstand a curing temperature to attach and protect all the components on the sensor support 356 with adhesive. In some examples, the sensor circuitry 352 may be attached to the support 356 with adhesive.

In some examples, the sensor circuitry 352 may include a liquid level sensor (e.g., digital liquid level sensor) and/or a strain or pressure sensor. In some examples, measurements from the sensor circuitry 352 may be utilized to determine a print liquid level. In some examples, the sensor circuitry 352 (e.g., liquid level sensor) may include an array of heaters and thermal sensors. For example, the sensor circuitry 352 may activate the array of heaters and measure temperature at different levels. Lesser temperatures may correspond to heaters and/or thermal sensors that are below the print liquid level. Greater temperatures may correspond to heaters and/or thermal sensors that are above the print liquid level. The measured temperatures may indicate the level of the print liquid due to the different specific heats of print liquid and air.

In some examples, the sensor circuitry 352 may include a strain sensor or pressure sensor. For example, the sensor circuitry 352 may include a strain gauge or strain gauges, piezoelectric pressure sensor(s), electromagnetic pressure sensor(s), and/or capacitive pressure sensor(s), etc. For instance, the strain sensor or pressure sensor may provide measurements that indicate a change in resistance, inductance, and/or capacitance that corresponds to a strain or pressure. In some examples, the strain sensor or pressure sensor may measure a structural strain (e.g., deflection deformation of a wall of the print component) of the print component and/or pressure in the reservoir 354. The print liquid reservoir 354 may contain print liquid. In some examples, the sensor circuitry 352 may be housed in the print liquid reservoir 354.

In some examples, the sensor circuitry 352 may include a combination of a print liquid level sensor and a strain or pressure sensor. Accordingly, the sensor circuitry 352 may provide measurements that indicate a print liquid level and a strain or pressure of the print component.

In some examples, the print component may include a lid 346 and a body 344. The lid 346 and the body 344 are structures for containing print liquid. For example, the lid 346 may be joined to the body 344 to form the print liquid reservoir 354. In some examples, the lid 346 and the body 344 may be made of a thermoplastic or a combination of thermoplastics. In some examples, the lid 346 may be welded and/or joined to the body 344 along a supply joint. The supply joint is an interface between the lid 346 and the body 344. In some examples, the lid 346 may be welded and/or joined to the body 344 using laser welding, ultrasonic welding, vibration welding, and/or adhesive.

In some examples, the sensor circuitry 352 may be coupled to an electrical connector 301. The electrical connector 301 may be an example of the electrical connector 101 described in relation to FIG. 1 and/or may be an example of the electrical connector 201 described in relation to FIG. 2. The electrical connector 301 may conduct electricity and/or electronic signals between the sensor circuitry 352 and the contact pads 304 of the electrical connector 301. For example, the electrical connector 301 may include routes for conducting electricity and/or electronic signals between the sensor circuitry 352 that is coupled to bonds of the electrical connector 301 (with gold wires, for instance) and the contact pads 304 of the electrical connector 301. In some examples, the electrical connector 301 may be overmolded with a protective material. The protective material may protect the electrical connector 301 from contact with the print liquid, which may degrade the electrical connector 301. In some examples, the electrical connector 301 may be routed from the inside of the print component to the outside of the print component through the supply joint or a wall of the print component. The electrical connector 301 may be utilized to communicate with a printer in some examples.

FIG. 3A and FIG. 3B Illustrate examples of some components that may be internally housed in the print component. In this example, a regulator assembly of the print component may include a pressure chamber 348 (e.g., a bag), a spring plate 358, and a lever 360. The regulator assembly may provide backpressure to the print component. In FIG. 3A, the pressure chamber 348 is illustrated inside the body 344, where some edges of the pressure chamber 348 (e.g., bag) may be folded along some edges of the body 344. Different shapes may be utilized for a pressure chamber, and/or a pressure chamber may change shape during operation. For example, the pressure chamber 348 may be shaped as an oblong oval in a stage of operation. In some examples, the spring plate 358 and/or lever 360 may be mounted to the lid 346. In some examples, the sensor circuitry 352 and/or sensor support 356 may be mounted to the lid 346. Other types of regulator assemblies may be utilized in some examples. For instance, other mechanical regulator assemblies and/or capillary media assemblies may be utilized with a reservoir 354 for the sensor circuitry 352. For example, the regulator assembly may be replaced with a block of foam in a similar position to work in a reservoir or ink chamber (with the sensor circuitry 352, for instance).

In some examples, the print component (e.g., the body 344) may include a port 350, a fill port 362, and/or an air interface port 364. The fill port 362 is a port for filling the print component with print liquid. The air interface port 364 is a port for inflating and/or deflating the pressure chamber 348. The port 350 may be utilized to supply print liquid. In the example illustrated in FIG. 3A, a rubber septum, a ball, and a spring are utilized to control port 350 access. In other examples, a port may include and/or utilize a split septum, or a film. In FIG. 3A, the sensor circuitry 352 and sensor support 356 are illustrated as being superimposed on the body 344 for clarity.

In some examples, the print component is filled through the fill port 362. A plug (e.g., plastic ball cork) may be utilized to close (e.g., seal) the fill port 362. Some (e.g., most) of the air remaining in the print component after filling with print liquid may be removed via the port 350. As the air is removed, an internal vacuum may be created that inflates the pressure chamber 348 (e.g., bag) while being resisted by the spring plate 358. The volume in the pressure chamber 348 may be sized to regulate (e.g., maintain) a pressure in a target range inside the print component during variations in temperature and/or altitude, and/or to prevent internal over-pressurization.

In some examples, when the print component is installed in a print head assembly, a first male needle interfaces with the port 350 and a second male needle interfaces with an air interface port 364. As print liquid is used and removed from the print component through the port 350, the pressure chamber 348 inflates and pushes on the lever 360 in the lid 346, which may open a port to allow air to bubble into the print component. The pressure chamber 348 may deflate accordingly to regulate the pressure in the print component. In some examples, when the print liquid is exhausted from the print component (e.g., when most or all of the print liquid has been expelled), some air may be passed through the port 350 (e.g., through the first male needle) into the print head assembly.

In some examples, when a new print component is installed or when the print head is to be purged for servicing, an air pump in the printer may be used to inflate (e.g., hyper-inflate) the pressure chamber 348 through the air interface port 364. When the pressure chamber 348 is inflated to a degree, the lid 346 and/or the body 344 may deflect (e.g., bulge). For example, a wall of the lid 346 and/or a wall of the body 344 may deflect. In some examples, the pressure chamber 348 may be inflated to occupy more volume inside the print liquid supply, which may cause deflection. Inflating the pressure chamber 348 for a newly installed print component may force print liquid into the print head assembly to prime the print head while air is pushed into the print component.

In some examples, sensor circuitry may be attached to the print component. In the example illustrated in FIG. 3A and FIG. 3B, the sensor circuitry 352 and sensor support 356 are attached to the lid 346. When the deflection (e.g., bulge) occurs, the sensor circuitry 352 (e.g., strain gauge) may detect the deflection. For example, the sensor circuitry 352 may produce measurements that indicate the deflection. The measurements may be communicated to a printer via the electrical connector 301 in some examples. For example, strain and/or pressure sensors may be utilized to provide feedback. For instance, the sensor circuitry 352 may be utilized to verify that a regulator assembly and/or pressure chamber are functioning. In some examples, the sensor circuitry 352 may be utilized to determine if there is a leak in the print component.

In some examples, sensor circuitry may include layers of sensors. For example, sensor circuitry may be manufactured using layers of silicon. In some examples, strain gauges may be located in a lower (e.g., bottom) layer, heaters may be located in a middle layer (e.g., a layer above the layer with the strain gauges), and thermal sensors may be located on an upper layer (e.g., on the face of the silicon). When the heaters are activated, the thermal sensors may detect the difference between the presence of air and print liquid, which may indicate the print liquid level. A signal or signals (e.g., data) indicating a print liquid level may be sent from the sensor circuitry 352 to the printer via the electrical connector 301. A signal or signals (e.g., data) indicating a strain and/or pressure may be sent from the sensor circuitry 352 to the printer via the electrical connector 301.

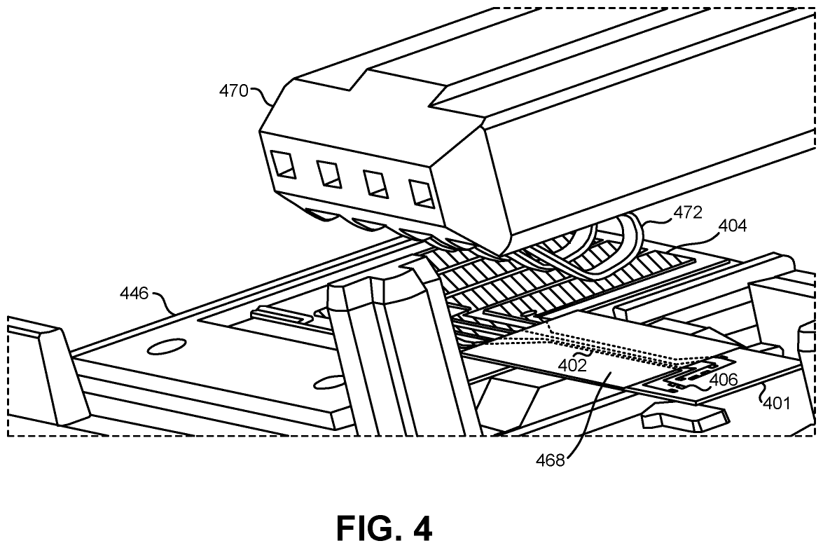

FIG. 4 is a perspective view diagram of an example of an electrical connector 401. The electrical connector 401 described in relation to FIG. 4 may be an example of the electrical connector 101 described in relation to FIG. 1, the electrical connector 201 described in relation to FIG. 2, and/or the electrical connector 301 described in relation to FIGS. 3A and 3B.

The electrical connector 401 includes contact pads 404, routes 402, and bonds 406. In this example, the electrical connector 401 is included in (e.g., supported by, attached to, mounted on, etc.) a lid 446 of a print component. A cutaway portion of the lid 446 is illustrated in FIG. 4. In this example, portions of the routes 402 are covered with protective material 468 (e.g., the protective film may be adhered over portions of the routes 402). In the example of FIG. 4, the contact pads 404 are in contact with spring connectors 472 of a host print system 470. A cutaway portion of the host print system 470 (e.g., printer) is illustrated in FIG. 4. A gold layer on the contact pads 404 may serve to lubricate the contact pads 404 to reduce friction with the spring connectors 472. The gold layer on the contact pads 404 may be thinner than the gold layer on the bonds 406.

In some examples, a lubricant (e.g., dielectric lubricant) may be applied to the contact pads 404 to reduce friction with the spring connectors 472. In some examples, the contact pads 404 may include a nickel layer (or a nickel alloy layer, such as a nickel-phosphorous (Ni—P) layer, for instance) under the gold layer to provide durability to the contact pads 404. In some examples, the contact pads 404 may include a copper layer under the nickel layer.

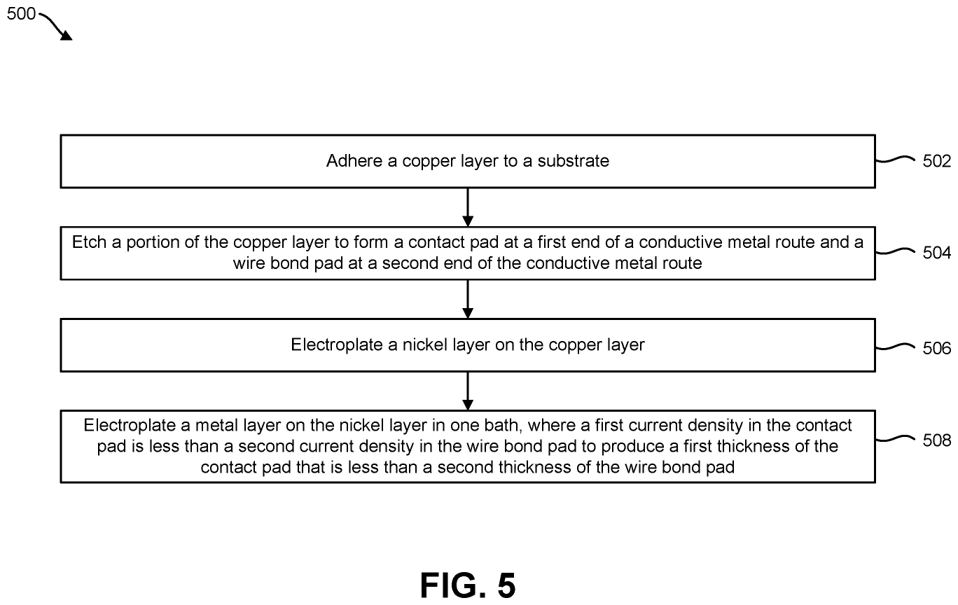

FIG. 5 is a flow diagram illustrating one example of a method 500 for manufacturing a conductive metal route. In some examples, the method 500 may be performed by a manufacturing machine or machines. The method 500 may include adhering 502 a copper layer to a substrate (e.g., polyimide, flexible polyimide film, etc.). For example, copper foil may be joined to the substrate using an adhesive.

The method 500 may include etching 504 a portion of the copper layer to form a contact pad at a first end of a conductive metal route and a wire bond pad at a second end of the conductive metal route. For example, photolithography may be utilized to create a pattern of the conductive metal route on the copper layer. A copper etch bath may be utilized to etch away copper foil that is not part of the conductive metal route.

The method 500 may include electroplating 506 a nickel layer on the copper layer. For example, an electric current may be applied to the conductive metal route (e.g., copper layer) in a bath of nickel solution, which may cause the nickel in the nickel solution to plate the conductive metal route (e.g., copper layer).

The method 500 may include electroplating 508 a metal layer on the nickel layer in one bath. For example, an electric current may be applied to the conductive metal route (e.g., nickel layer and copper layer) in a bath of metal solution, which may cause the metal in the metal solution to plate the conductive metal route. In some examples, the metal layer may be a gold layer and/or a palladium layer. For instance, the metal layer may include a palladium layer and/or a gold layer.

In some examples, a first current density in the contact pad may be less than a second current density in the wire bond pad to produce a first thickness of the contact pad that is less than a second thickness of the wire bond pad. For example, the contact pad may have a larger area than the wire bond pad, and may accordingly have a lower current density than the wire bond pad. The higher current density in the wire bond pad may cause the metal to plate more quickly on the wire bond pad, thereby producing a greater thickness on the metal bond pad.

The electroplating 508 of the metal layer may be performed in a single bath. For example, after a bath to electroplate 506 the nickel layer on the copper layer, one bath (e.g., gold bath or palladium bath) may be utilized to electroplate 508 the metal layer, where the metal layer has different thicknesses on the contact pad and the wire bond pad.

1. A replaceable print component to connect to a host print system comprising an electrical connector, comprising:
a contact pad at a first end of a route; and
a bond at a second end of the route, wherein the contact pad and the bond comprise a copper layer on a substrate, a nickel layer on the copper layer, and a gold layer on the nickel layer, wherein the gold layer has a first thickness on the contact pad and has a second thickness on the bond, wherein the second thickness is greater than the first thickness.

2. The print component of claim 1, wherein the bond at the second end is a wire bond pad.

3. The print component of claim 1, wherein the gold layer with the first thickness and the second thickness is formed in one gold bath.

4. The print component of claim 1, wherein the second thickness is greater than the first thickness by at least 20 nanometers.

5. The print component of claim 1, wherein the contact pad has a first contact surface area that is greater than a second surface area of the bond.

6. The print component of claim 5, wherein the first contact surface area is greater than the second surface area by a ratio of at least 10.

7. The print component of claim 1, wherein the contact pad and the bond are on a single side of the substrate.

8. The print component of claim 1, further comprising a second route, wherein the route is a serial data line and the second route is a clock line.

9. The print component of claim 8, further comprising a third route and a fourth route, wherein the third route is a power line and the fourth route is a ground line.

10. The print component of claim 1, further comprising sensor circuitry coupled to the bond, wherein the sensor circuitry is to detect a print liquid level, a pressure, or a strain.

11. The print component of claim 1, wherein the copper layer, the nickel layer, and the gold layer span the route.

12. A print liquid container, comprising:
a plurality of metal routes, wherein each of the metal routes comprises a contact pad and a wire bond pad, wherein each contact pad has a greater area and a lesser thickness than each corresponding wire bond pad, and wherein each of the metal routes comprises a copper layer, a nickel layer on the copper layer, and a gold layer on the nickel layer.

13. The print liquid container of claim 12, wherein each of the contact pads has a lower current density than each corresponding wire bond pad during manufacturing to produce the lesser thickness.

14. A method for manufacturing a conductive metal route, comprising:
adhering a copper layer to a substrate;
etching a portion of the copper layer to form a contact pad at a first end of a conductive metal route and a wire bond pad at a second end of the conductive metal route;
electroplating a nickel layer on the copper layer; and
electroplating a metal layer on the nickel layer in one bath, wherein a first current density in the contact pad is less than a second current density in the wire bond pad to produce a first thickness of the contact pad that is less than a second thickness of the wire bond pad.

15. The method of claim 14, wherein the metal layer includes a gold layer or a palladium layer.
